(19) United States
(12) Patent Application Publication
(10) Pub. No.: US 2006/0289960 A1
(43) Pub. Date: Dec. 28, 2006

(54) Structure improvement of depletion region in p-i-n photodiode

(75) Inventor: Yen-Hsiang Wu, Jhongli City (TW)

Correspondence Address: TROXELL LAW OFFICE PLLC, SUITE 1404, 5205 LEESBURG PIKE, FALLS CHURCH, VA, 22041, US

(73) Assignee: National Central University

(21) Appl. No.: 11/158,065

(22) Filed: Jun. 22, 2005

(51) Int. Cl. H01L 29/221

(52) U.S. Cl. 257/458

(57) ABSTRACT

The present invention with a structure of depletion region improves the product of output power and bandwidth of a photodetector and prevents the drifting velocity of electron from slowing down under a bias, which can be applied to a photodetector of communicative wavelength over optical fiber.

### FIELD OF THE INVENTION

The present invention relates to a structure of depletion region; more particularly, relates to improving the product of output power and bandwidth of a photodetector and preventing the drifting velocity of electron from slowing down under a high bias.

### DESCRIPTION OF THE RELATED ART

In the development of high-speed photodetector, one of the key targets is the product of output power and bandwidth. When a traditional p-i-n photodiode is put under an irradiation using a high optical power, the speed performance becomes worse and the maximum electric output power becomes lower than usual because the added electric field is shielded by the space electric field reacted by inner photo-excited carriers. Hence, then, a Uni-traveling Carrier Photodetector (UTC-PD) is provided, where the light-absorbing material of InP. With p-i-n photodiode is changed from the i-layer to a p-type doped layer and the original i-layer is substituted with a non light-absorbing material of InP. With such a structure, the effect of being shielded by the space electric field is solved and the accumulation of electric holes to its fullness in the p-i-n photodiode is slowed down, which can greatly improve the product of output power and bandwidth and materials of such a structure is merchandized. But, when operated under a high power, a great deal of photocurrent will pass by a load resistance and produce an electric field with a polarity opposite to the bias added to the optical detector. So, the high power from the traditional UTC-PD is usually produced under a high bias to alleviate the effect of the load resistance. Nevertheless, the high bias will slow down the transmitting velocity of electrons, accompanying by a trade-off among velocity, efficiency and maximum power concerning area size, and also accompanying by a trade-off between the maximum output current and the breakdown voltage in a doped collector layer.

Please refer to FIG. 10, which is a view showing a bandgap figure of a p-i-n detector under an irradiation with a low optical power (shown with a dotted line) and under an irradiation of a high optical power (shown with a solid line) according to a prior art. As shown in the figure, under an irradiation with a high optical power 21, photo-generated holes with slower velocity are not discharged so that a space electric shielding field with a polarity opposite to the bias added is formed to greatly lower an electric field at the center of a light-absorbing layer. So, the moving velocities of photo-excited carriers in this area are greatly lowered to greatly worsen the velocity performance of the whole structure and limit the output power.

To solve this problem, the light-absorbing layer can be changed from the undoped depletion region into a p-type doped layer and the original depletion region is substituted with a non light-absorbing material so that the transmission mechanism for the material is changed from bipolar carriers (electron 22 and hole 23) into a uni-traveling carrier (UTC), whose bandgap figure under an irradiation with a low optical power (a dotted line) and under an irradiation of a high optical power (a solid line) is shown in FIG. 11. Although a very high output power and velocity performance can be obtained with this kind of detector, the following disadvantages still exist.

1. As shown in FIG. 12, this kind of UTC photodetector can obtain the effect of a ballistic transmission only under a low bias, where the power performance of the detector will be predominated by outside load resistance effect. When a high power is generated, a great amount of photocurrent will pass by a load resistance and produce an electric field with a polarity opposite to the bias of the detector. So, for a high power performance, a UTC component is usually operated under a higher bias while sacrificing carrier drifting speed.

2. Yet, as shown in FIG. 11, when a UTC structure is operated under a high bias, a current blocking occurs in the original undoped layer 31 and electrons will be accumulated at the edge of the energy band to its fullness with a lowered velocity. The best way to solve this problem directly is to be doped with an n-type material to improve its power performance while sacrificing its breakdown voltage though. So, a trade-off between the breakdown voltage and the output power exists in this layer concerning the doping.

3. The full electric power and the maximum current a unit area can provide are of certain values, so that a component with a bigger area contains a bigger power capacity and a better efficiency performance. But, the velocity of a large component will be seriously limited by the RC (resistance-capacitance) delay time so that, even though a UTC structure can successfully imp roves the product of the power and the bandwidth a trade-off between the maximum output power (and efficiency) and the bandwidth concerning are a size still exists.

### SUMMARY OF THE INVENTION

Therefore, the main purpose of the present invention is to improve the product of output power and bandwidth of a photodetector and to prevent the drifting velocity of electron from slowing down under a high bias, which can be applied to a photodetector of communicative wave length over optical fiber.

To achieve the above purpose, the present invention is a structure improvement of depletion region in a p-i-n photodiode, where, from top to bottom, an epitaxy layer of the photodiode comprises a first p-type doped layer, a first n-type doped layer, a second p-type doped layer, an undoped layer and a second n-type doped layer, forming a p-n-p-i-n epitaxy layer grown on any kin d of substrate of doped or semi-insulated diode to be applied to a photo-receiver for fiber communication or a photoelectric mixer for radio astronomy. Accordingly, a novel structure improvement of depletion region in a p-i-n photodiode is obtained.

### BRIEF DESCRIPTIONS OF THE DRAWINGS

The present invention will be better understood from the following detailed descriptions of the preferred embodiments according to the present invention, taken in conjunction with the accompanying drawings, in which

FIG. 1 is a band gap figure according to the present invention;

FIG. 2 is a view showing distribution of electric field under different doping profiles and distribution of the corresponding p-n density according to the present invention;

FIG. 3 is a view showing a relationship between electron velocity and electric field according to the present invention

FIG. 4 is a view showing measurements of efficiency of photodiode with different sizes of area according to the present invention;

FIG. 5 is a view showing measurements of power with different biases according to the present invention;

FIG. 6 is a view showing frequency response by measurement and simulation according to the present invention;

FIG. 7 is a view showing bandwidths related to photocurrents with different biases according to the present invention;

FIG. 8 is a view showing a side-irradiation photodetector according to the present invention; and

FIG. 9 is a view showing a vertical-irradiation photodetector according to the present invention.

FIG. 10 is a view showing a bandgap figure of a p-i-n detector under an irradiation with a low optical power and under an irradiation of a high optical power according to a prior art;

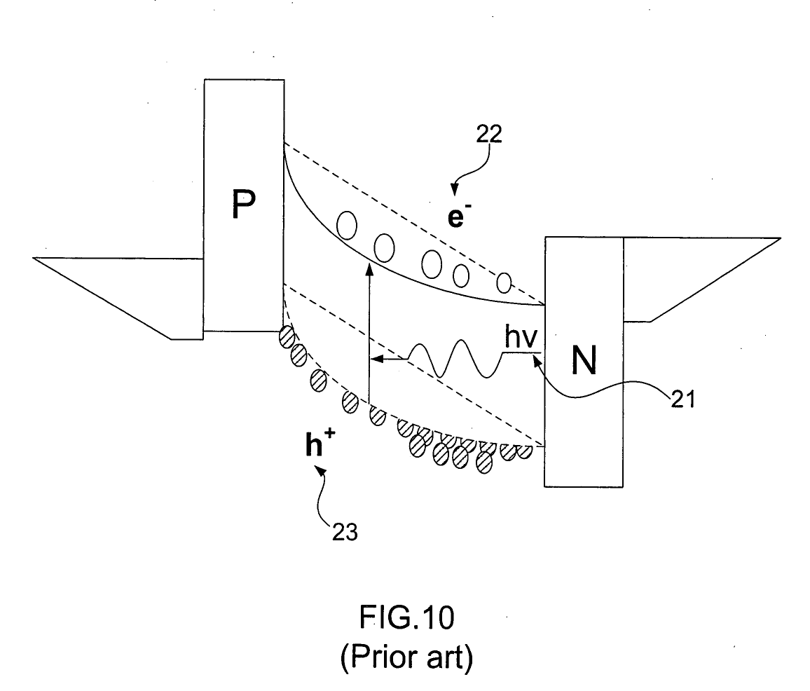

FIG. 11 is a view showing a bandgap figure of a UTC (Uni-traveling Carrier) detector under an irradiation with a low optical power and under an irradiation of a high optical power according to a prior art;

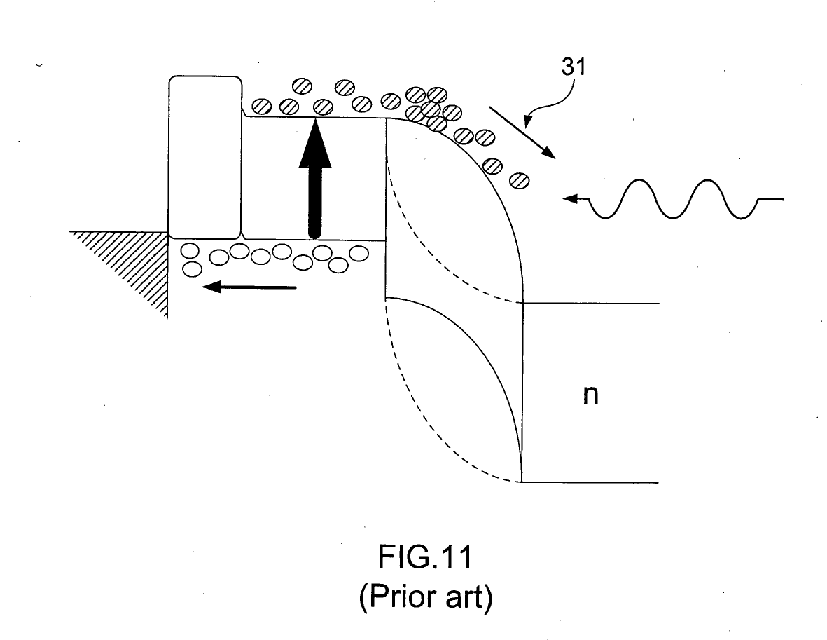

FIG. 12 is a view showing a relationship between electron velocity and electric field according to a prior art;

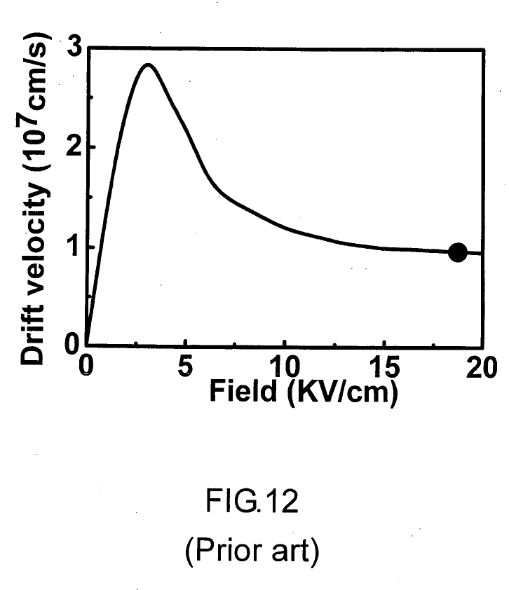

### DESCRIPTION OF THE PREFERRED EMBODIMENTS

The following descriptions of the preferred embodiments are provided to understand the features and the structures of the present invention.

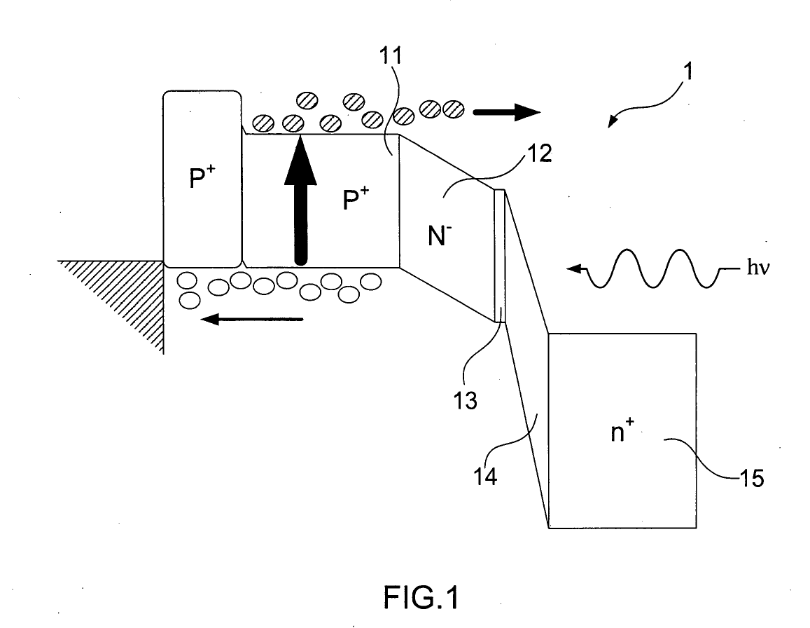

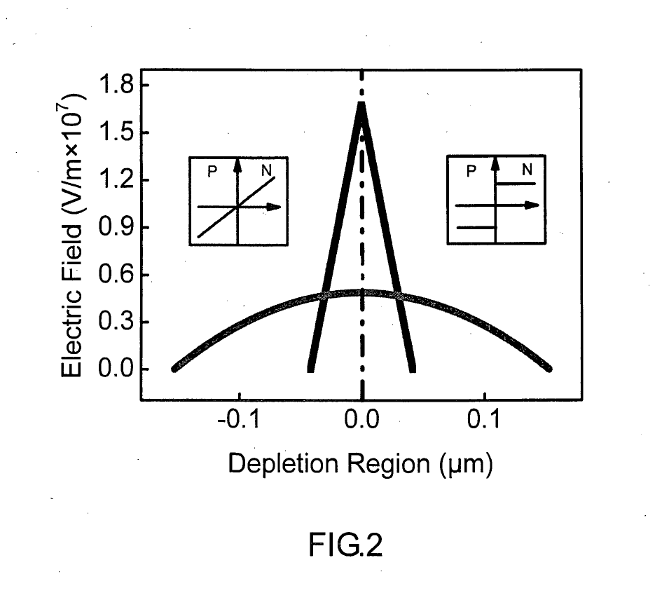

Please refer to FIG. 1, which is a structural view according to the present invention. As shown in the figure, the present invention is a structure improvement of depletion region in a p-i-n photodiode, where its epitaxy layer 1 comprises a first p-type doped layer 11, a first n-type doped layer 12, a second p-type doped layer 13, an undoped layer 14, and a second n-type doped layer 15, to form a p-n-p-i-n epitaxy layer grown on any doped diode or semi-insulated diode made of GaAs, InP, GaN, AlN, Si or GaSb. The first p-type doped layer 11 is made of a light-absorbing material to be a light-absorbing layer; and, is graded doped to accelerate electron discharge. The first n-type doped layer 12 is made of a material of ballistic transmission to accelerate the transmission of carrier; and, is graded doped to increase a breakdown voltage and a maximum output current (as shown in FIG. 2). The second p-type doped layer 13 and the undoped layer 14 is a non light-absorbing ternary or four-component alloy. With proper thickness and proper doping, the second p-type doped layer 13 obtains a ballistic transmission so that the first n-type doped layer 12 is operated under a peak carrier drifting speed. The second n-type doped layer 15 is a high-doped layer as an Ohmic contact. The epitaxy layer 1 comprises compound diode, such as GaAs, InP, GaN, and its alloy, such as AlGaN, InGaN, InGaAs, InGaAsP, InAlAs, InP, InAlGaAs, GaAs, AlGaAs; or, comprises a column IV element, such as Si, and its alloy, such as SiGe Consequently, a novel structure improvement of depletion region in a p-i-n photodiode is obtained.

In the UTC structure according to the present invention, a second p-type doped layer 13 and an undoped layer 14 are added to the first n-type doped layer 12 to obtain the following advantages:

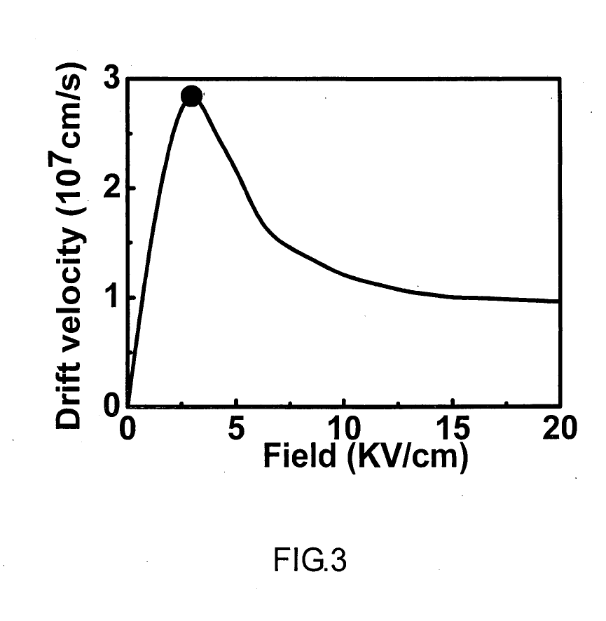

1. By using such a structure, most of the electric field originally covered on the first n-type doped layer 12 is transferred to the two ends of the undoped layer 14 and only a little of the electric field is transferred to the first n-type doped layer 12 so that, most of the time when electrons are drifting, they are transmitted under a ballistic velocity in the first n-type doped layer 12 (as shown in FIG. 3); and seldom are transmitted under a low velocity in the undoped layer 14. By such a design, a component according to the present invention obtains the effect of a ballistic transmission under a high bias while the effect of a load current, which will screen the external applied electric field, is avoided.

2. In a UTC photodetector with high power, a depletion layer is usually highly doped to improve power performance, so that the breakdown voltage of the p-n interface is usually lowered. A fixed doping is a pt to cause a breakdown at the p-n interface; yet, a smaller electric field is obtained at the interface by a graded doping to restrain the breakdown (as shown in FIG. 2) so that the maximum output current can be enlarged with some high doping. In the present invention, only little electric field is deposed on the first n-type doped layer 12 so that, by combining the technology of high doping and the other characteristics of the present invention, the electric power output is improved without sacrificing the breakdown voltage

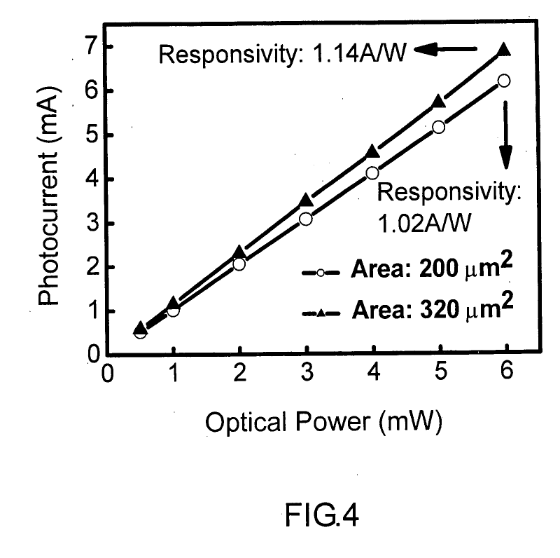

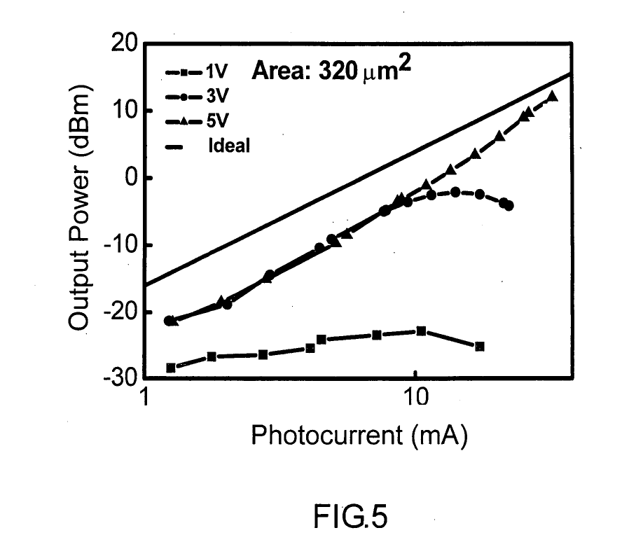

As shown in FIG. 4 and FIG. 5, the present invention obtains a characteristic of a ballistic transmission of carrier under a high bias, so that, when compared with a traditional UTC structure, the component according to the present invention can be of bigger size under the same bandwidth; and, owing to the bigger size, the performances of the maximum power and the efficiency are much better than can those UTC structure without using the present invention.

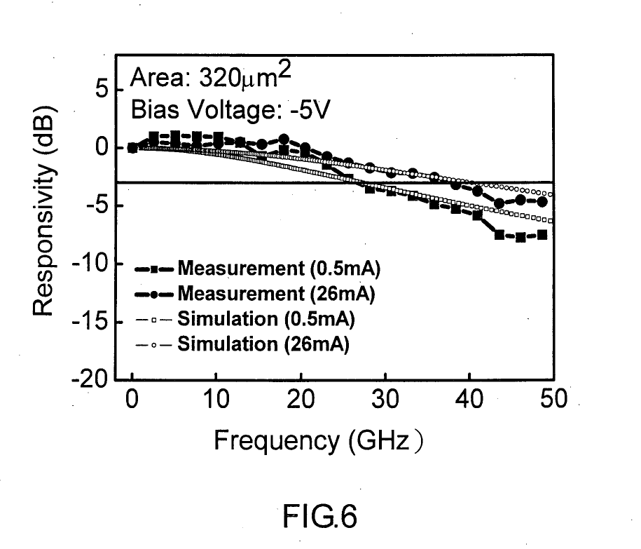

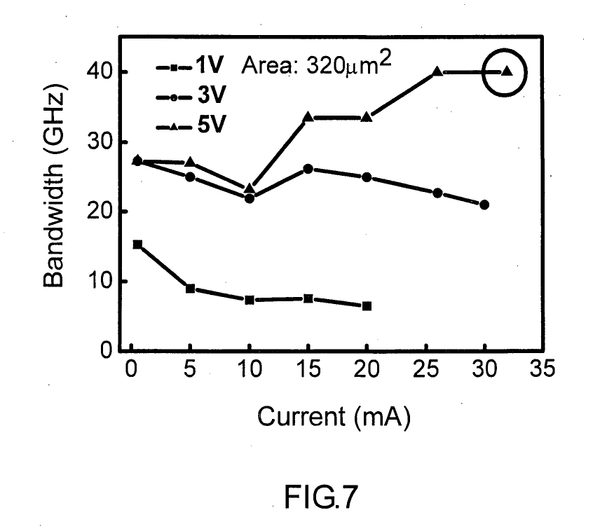

Concerning substantiating a component according to the present invention, it is prepared by growing the above structure on a general substrate together with a general exposed development etching. Please refer to FIG. 6 and FIG. 7, which, according to the present invention, are a view showing frequency response under a low photocurrent (0.5 mA) and a high photocurrent (26 mA) by measurement and simulation, and a view showing bandwidths for different photocurrents for a big component under different biases. As what can be seen obviously, the bandwidths are predominated by the R C (resistance-capacitance) delay time under low power; yet, when a high photocurrent is generated, the bandwidth is obviously improved owing to the effect of the ballistic transmission. The product of the bandwidth and the efficiency is much greater than the publication value for the traditional UTC structure.

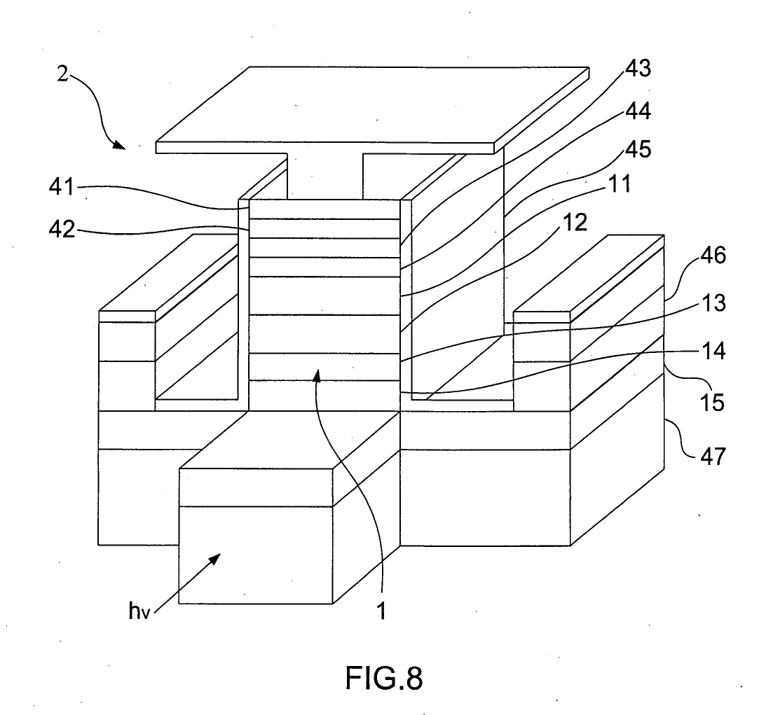

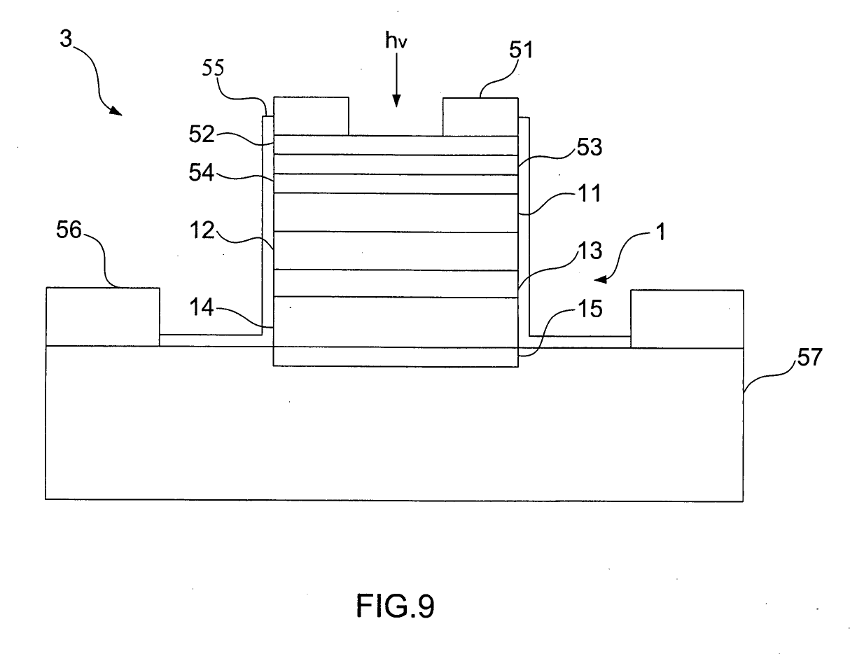

Thus, as shown in FIG. 8, the epitaxy layer 1 according to the present invention is applied to a side-irradiating detector 2, which comprises a P-metal 41, a p-InGaAs 42 as a contact layer, a p-InP 43 as a cladding layer, a p-InAlGaAs 44 as a diffusion block, a BCB (Benzocyclobutene) polyimide 45, a N-metal 46, a p-InGaAs 11 as the first p-type doped layer, a n-InAlGaAs 12 as the first n-type doped layer, a p⁺-InAlAs 13 as the second p-type doped layer, a U—InAlAs 14 as the undoped layer, a second n-type doped layer 15 for a coupling guide, and a substrate 47 for a fiber guide. As shown in FIG. 9, the epitaxy layer 1 according to the present invention is applied to a vertical-irradiating detector 3, which comprises a P-metal 51, a p-InGaAs 52 as a contact layer, a p-InP 53 as a cladding layer, a p-InAlGaAs 54 as a diffusion block, a BCB polyimide 55, a N-metal 56, a p-InGaAs 11 as the first p-type doped layer, a n-InAlGaAs 12 as the first n-type doped layer, a p⁺-InAlAs 13 as the second p-type doped layer, a U—InAlAs 14 as the undoped layer, a second n-type doped layer 15, and a substrate 57 of InP—Si.

In addition the present invention has the following advantages: 1) Most of the electric field is deposed on the undoped layer 14 so that, even when the components are operated under a high bias, the first n-type doped layer 12 still comprises lower electric field yet with a ballistic transmission. 2) The doping in the first n-type doped layer 12 can be heavy to improve output power with out sacrificing breakdown voltage. 3) The trade-off between maximum output power (and efficiency) and bandwidth concerning area size can be released.

To sum up, the present invention is a structure improvement of depletion region in a p-i-n photodiode, which prevent the drifting velocity of electron from slowing down under a high bias; and can be applied to a digital-analog communication system or to a photoelectric signal generator in the field of radio astronomical exploration.

The preferred embodiment herein disclosed is not intended to unnecessarily limit the scope of the invention. Therefore, simple modifications or variations belonging to the equivalent of the scope of the claims and the instructions disclosed herein for a patent are all with in the scope of the present invention.

What is claimed is:

1. A structure improvement of depletion region in a p-i-n photodiode, characterized in that
an epitaxy layer of said p-i-n photodiode comprises:
(a) a first p-type doped layer;
(b) a first n-type doped layer;
(c) a second p-type doped layer;
(d) an undoped layer; and
(e) a second n-type doped layer, to obtain a p-n-p-i-n epitaxy layer deposed on a substrate made of diode selected from a group consisting of doped diode and semi-insulated diode.

2. The structure improvement according to claim 1, wherein said epitaxy layer comprises a compound diode and an alloy of said compound diode.

3. The structure improvement according to claim 2,
wherein said compound diode is made of a material selected from a group consisting of GaAs, InP and GaN; and
wherein said alloy of said compound diode is made of a material selected from a group consisting of AlGaN, InGaN, InGaAs, InGaAsP, InAlAs, InP, InAlGaAs, GaAs and AlGaAs.

4. The structure improvement according to claim 1, wherein said epitaxy layer comprises a diode made of a column IV element and an alloy of said diode made of said column IV element.

5. The structure improvement according to claim 4,
wherein said diode made of said column IV element is made of Si;
wherein said alloy of said diode made of said column IV element is made of SiGe.

6. The structure improvement according to claim 1, wherein said p-type doped layer is made of a light-absorbing material as a light-absorbing layer being graded doped to accelerate electron discharge.

7. The structure improvement according to claim 1,
wherein said first n-type doped layer is made of a non light-absorbing material of ballistic transmission to speed up carrier transmission; and
wherein said first n-type doped layer is graded doped to increase a breakdown voltage and a maximum output current.

8. The structure improvement according to claim 1, wherein said second p-type doped layer and said undoped layer a re made of an alloy selected from a group consisting of a ternary alloy and a four-component alloy to operate said n-type doped layer with a peak carrier drifting speed.

9. The structure improvement according to claim 1, wherein said second n-type doped layer is made of a high-doped diode to obtain an Ohmic contact layer.

10. The structure improvement according to claim 1, wherein said substrate is made of a material selected from GaAs, InP, GaN, AlN, Si and GaSb

11. The structure improvement according to claim 1, wherein said epitaxy layer is located in a side-irradiating detector.

12. The structure improvement according to claim 1, wherein said epitaxy layer is located in a vertical-irradiating detector.
